(19) United States
(12) Patent Application Publication
(10) Pub. No.: US 2012/0298954 A1
(43) Pub. Date: Nov. 29, 2012

(54) SEMICONDUCTOR LIGHT EMITTING DEVICE AND MANUFACTURING METHOD OF THE SAME

(75) Inventors: Sang Yeon KIM, Seongnam (KR); Jong Rak Sohn, Hwaseong (KR); Gi Bum Kim, Hwaseong (KR); Su Yeol Lee, Seongnam (KR); Yong II Kim, Hwaseong (KR)

(73) Assignee: SAMSUNG ELECTRONICS CO., LTD.

(21) Appl. No.: 13/480,184

(22) Filed: May 24, 2012

(30) Foreign Application Priority Data
May 24, 2011 (KR) 10-2011-0048854

(51) Int. Cl. H01L 33/06; H01L 33/42

(52) U.S. Cl. 257/13; 438/47; 257/E33.008; 257/E33.064

(57) ABSTRACT

There are provided a semiconductor light emitting device and a manufacturing method of the same. The semiconductor light emitting device includes a light emitting structure including first and second conductive semiconductor layers with an active layer interposed therebetween; first and second bonding electrodes connected to the first and second conductive semiconductor layers, respectively; a transparent electrode layer formed on the second conductive semiconductor layer; a plurality of nano structures formed on the transparent electrode layer; and a passivation layer formed to cover the plurality of nano-structures, wherein refractive indexes of the transparent electrode layer, the plurality of nano-structures, and the passivation layer may be sequentially reduced.

### CROSS-REFERENCE TO RELATED APPLICATIONS

This application claims the priority of Korean Patent Application No. 10-2011-0048854 filed on May 24, 2011, in the Korean Intellectual Property Office, the disclosure of which is incorporated herein by reference.

### BACKGROUND OF THE INVENTION

1. Field of the Invention

The present invention relates to a semiconductor light emitting device and a manufacturing method of the same, and more particularly, to a semiconductor light emitting device and a manufacturing method of the same that improve light extraction efficiency.

2. Description of the Related Art

A semiconductor light emitting diode (LED) as a device converts electrical energy into light energy, generated while electrons and holes are recombined with each other to emit light due to materials included therein. LEDs are widely used as in general illumination devices, display devices, and light sources at present, and the further development thereof is being accelerated.

In particular, with the commercialization of a cellular phone keypad, a side mirror turn signal, and a camera flash, using a gallium nitride (GaN)-based light emitting diode of which the development and entry into wide-spread use are completed, the development of general illumination devices using light emitting diodes has been actively undertaken in recent years. Applications thereof including backlight units of large-sized TVs, vehicle headlights, and general illumination devices have progressed to large-sized, high-output, and high-efficiency products from small-sized portable products, such that light sources having characteristics required byproducts in which they are intended for use are required.

Therefore, as a scheme for acquiring a high light-intensity and high light-efficiency light emitting diode, a light emitting diode structure in which a plurality of nano-structures are formed therein is used.

### SUMMARY OF THE INVENTION

An aspect of the present invention provides a semiconductor light emitting device in which light extraction efficiency is increased.

Further, another aspect of the present invention provides a manufacturing method of the semiconductor light emitting device.

According to an aspect of the present invention, there is provided a semiconductor light emitting device, including: a light emitting structure including first and second conductive semiconductor layers with an active layer interposed therebetween; first and second bonding electrodes connected to the first and second conductive semiconductor layers, respectively; a transparent electrode layer formed on the second conductive semiconductor layer; a plurality of nano structures formed on the transparent electrode layer; and a passivation layer formed to cover the plurality of nano-structures, wherein refractive indexes of the transparent electrode layer, the plurality of nano-structures, and the passivation layer are sequentially reduced.

The transparent electrode layer may be a transparent conductive oxide layer or a transparent conductive nitride layer and, and specifically, the transparent electrode layer may be formed of at least one selected from a group consisting of Indium Tin Oxide (ITO), Zinc-doped Indium Tin Oxide (ZITO), Zinc Indium Oxide (ZIO), Gallium Indium Oxide (GIO), Zinc Tin Oxide (ZTO), Fluorine-doped Tin Oxide (FTC)), Aluminum-doped Zinc Oxide (AZO), Gallium-doped Zinc Oxide (GZO), In₄Sn₃O₁₂, and Zn₍₁₋ₓ₎MgₓO (Zinc Magnesium Oxide, 0≦x≦1).

The plurality of nano-structures may be formed of a transparent conductive zinc oxide (ZnO)-based compound and the plurality of nano-structures may be formed by using the transparent electrode layer as a seed layer.

The passivation layer may be formed of one selected from a group consisting of SiO₂, SiON, SiNₓ, and a combination thereof.

The passivation layer may have an opening and the second bonding electrode and the second conductive semiconductor layer may be connected therethrough.

The transparent electrode layer may include an opening for formation of the second bonding electrode therein, and the second conductive semiconductor layer and the second bonding electrode may be connected to each other may be formed on.

The transparent electrode layer may have an opening and the second bonding electrode and the second conductive semiconductor layer may be connected therethrough.

According to another aspect of the present invention, there is provided a manufacturing method of a semiconductor light emitting device, including: forming a light emitting structure including first and second conductive semiconductor layers with an active layer interposed therebetween on a substrate; forming a transparent electrode layer on the second conductive semiconductor layer; forming a plurality of nano structures on the transparent electrode layer; and forming a passivation layer to cover the plurality of nano-structures, wherein refractive indexes of the transparent electrode layer, the plurality of nano-structures, and the passivation layer are sequentially reduced.

The manufacturing method of a semiconductor light emitting device may further include removing the transparent electrode layer and forming a second bonding electrode connected to the second conductive semiconductor layer.

The transparent electrode layer may be a transparent conductive oxide layer and specifically, the transparent electrode layer may be formed of at least one selected from a group consisting of Indium Tin Oxide (ITO), Zinc-doped Indium Tin Oxide (ZITO), Zinc Indium Oxide (ZIO), Gallium Indium Oxide (GIO), Zinc Tin Oxide (ZTO), Fluorine-doped Tin Oxide (FTC)), Aluminum-doped Zinc Oxide (AZO), Gallium-doped Zinc Oxide (GZO), In₄Sn₃O₁₂, and Zn₍₁₋ₓ₎MgₓO (Zinc Magnesium Oxide, 0≦x≦1).

The passivation layer may be formed of one selected from a group consisting of SiO₂, SiON, SiNₓ, and a combination thereof and in this case, the passivation layer may be formed by a CVD method or a sputtering method.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view of a semiconductor light emitting device according to a first embodiment of the present invention;

FIG. 2 is a perspective view in which the semiconductor light emitting device of FIG. 1 is partially cut away;

FIG. 3 is a side cross-sectional view of a semiconductor light emitting device according to a second embodiment of the present invention; and

FIGS. 4 to 11 are schematic diagrams simply showing a manufacturing method of the semiconductor light emitting device according to the first embodiment of the present invention.

### DETAILED DESCRIPTION OF THE EMBODIMENTS

Embodiments of the present invention will now be described in detail with reference to the accompanying drawings.

The embodiments provide the scope of the present invention to those skilled in the art by way of examples. Therefore, the present invention is not limited to the embodiments disclosed below, but may be implemented in various forms disclosed in the appended claims.

Accordingly, the shapes and sizes of elements in the drawings may be exaggerated for clear description and like reference numerals refer to like elements throughout the drawings.

First, a semiconductor light emitting device according to an embodiment of the present invention will be described and thereafter, a manufacturing method of the semiconductor light emitting device according to an embodiment of the present invention will be described.

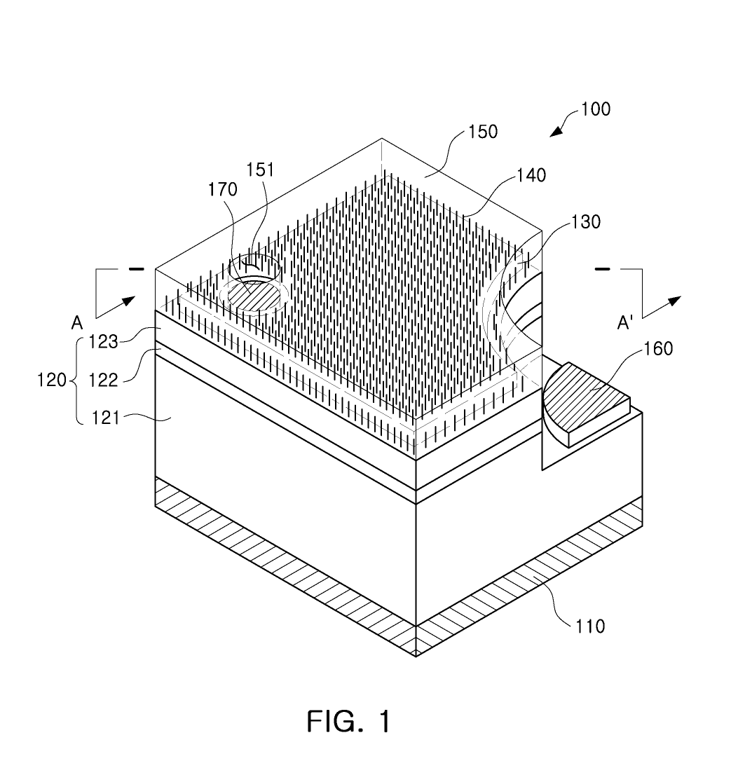

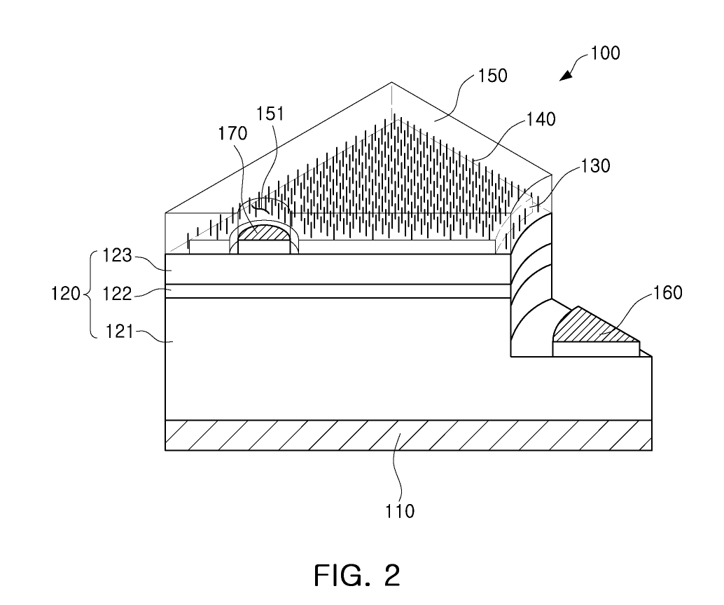

FIG. 1 is a perspective view of a semiconductor light emitting device 100 according to a first embodiment of the present invention. FIG. 2 is a perspective view in which the semiconductor light emitting device 100 of FIG. 1 is partially cut away.

As shown in FIGS. 1 and 2, the semiconductor light emitting device 100 according to the first embodiment of the present invention may include a light emitting structure 120, a transparent electrode layer 130 formed on an upper part of the light emitting structure 120, a plurality of nano-structures 140 formed in the transparent electrode layer 130, and a passivation layer 150 formed on the plurality of nano-structures 140; and refractive indexes of the transparent electrode layer 130, the plurality of nano-structures 140, and the passivation layer may be sequentially reduced. The semiconductor light emitting device may be a top light emitting-type light emitting device having a horizontal structure that emits light toward a top surface of a substrate (upward from the semiconductor light emitting device 100 as viewed in FIG. 1).

The light emitting structure 120 may include a first conductive semiconductor layer 121 and a second conductive semiconductor layer 123 with an active layer 122 interposed therebetween, on a substrate 110. The light emitting structure 120 has a structure in which the active layer 122 and the second conductive semiconductor layer 123 are mesa-etched to expose a partial area of the first conductive semiconductor layer 121.

The substrate 110 indicates a general wafer for manufacturing of the semiconductor light emitting device 100 and may use a transparent substrate of Al₂O₃, ZnO, or LiAl₂O₃ and in the embodiment, may use a sapphire substrate.

The first conductive semiconductor layer 121 may be a III-V group nitride semiconductor material and for example, an n-GaN layer. The second conductive semiconductor layer 123 may be a III-V group nitride semiconductor layer and for example, a p-GaN layer or a p-GaN/AlGaN layer.

The active layer 122 may be a GaN-based III-V group nitride semiconductor layer, which is InₓAl_{y}Ga_{1-x-y}N (0≦x≦1, 0≦y≦1, and 0≦x+y≦1) and a multi-quantum well (MQW) in which a quantum barrier layer and a quantum well layer are alternately stacked or a single quantum well. For example, the active layer 122 may have a GaN/InGaN/GaN MQW or GaN/AlGaN/GaN MQW structure.

The transparent electrode layer 130 may be formed on the second conductive semiconductor layer 123. The transparent electrode layer 130 may be formed of any one of a transparent conductive oxide and a transparent conductive nitride. A forming material of the transparent electrode layer 130 may be at least one material selected from a group consisting of Indium Tin Oxide (ITO), Zinc-doped Indium Tin Oxide (ZITO), Zinc Indium Oxide (ZIO), Gallium Indium Oxide (GIO), Zinc Tin Oxide (ZTO), Fluorine-doped Tin Oxide (FTC)), Aluminum-doped Zinc Oxide (AZO), Gallium-doped Zinc Oxide (GZO), In₄Sn₃O₁₂, and Zn₍₁₋ₓ₎MgₓO (Zinc Magnesium Oxide, 0≦x≦1).

In the semiconductor light emitting device 100, when a predetermined voltage is applied between a first bonding electrode 160 and a second bonding electrode 170, electrons and holes are injected into the active layer 122 from the first conductive semiconductor layer 121 and the second conductive semiconductor layer 123, respectively, to be recombined with each other, and as a result, light may be generated from the active layer 122.

A plurality of nano structures 140 may be formed on the transparent electrode layer 130. The plurality of nano-structures 140 may be formed to have a refractive index lower than the refractive index of the transparent electrode layer 130. In this case, the plurality of nano-structures 140 may be formed of a transparent conductive zinc oxide (ZnO)-based compound.

The transparent conductive zinc oxide (ZnO)-based compound may have at least one component among elements such as aluminum (Al), chrome (Cr), molybtenum (Mo), silicon (Si), Germanium (Ge), indium (In), lithium (Li), gallium (Ga), magnesium (Mg), zinc (Zn), beryllium (Be), molybdenum (Mo), vanadium (V), copper (Cu), iridium (Ir), rhodium (Rh), ruthenium (Ru), tungsten (W), cobalt (Co), nickel (Ni), manganese (Mn), titanium (Ti), tantalum (Ta), cadmium (Cd), and lanthanum (La) added thereto in order to control an electron concentration, an energy band gap, an optical refractive index, and the like, of the plurality of nano-structures 140.

The plurality of nano-structures 140 may be formed to have various shapes, that is, a columnar shape, a needle-like shape, a tubular shape, and a platter shape, among polygons having a circular, rectangular or hexagonal horizontal cross-sectional shape. The length of the plurality of nano-structures 140 may be controlled by controlling a reaction time during a growth temperature period during growth of the plurality of nano-structures 140.

The plurality of nano-structures 140 may be grown on the transparent electrode layer 130 by using a chemical vapor deposition (CVD) method, a molecular beam epitaxy (MBE) method, and a hybrid vapor phase epitaxy (HVPE) method, but when the plurality of nano-structures 140 are grown by using the CVD method, a production process is relatively simple and production costs are low.

The plurality of nano-structures 140 may be heat-treated at a temperature of 800° C. or lower under an atmosphere of oxygen (O₂), nitrogen (N₂), hydrogen (H2), argon (Ar), air, or in a vacuum, in order to improve light transmittance and electrical conductivity of the plurality of nano-structures 140.

The plurality of nano-structures 140 may be plasma-treated using oxygen (O₂), nitrogen (N₂), hydrogen (H2), and argon (Ar) ions at the temperature of 800° C. or below, in order to improve optical and electrical features of the plurality of nano-structures 140.

The passivation layer 150 may be formed on the plurality of nano-structures 140 to cover the plurality of nano-structures 140. The passivation layer 150 may seal the plurality of nano-structures 140 to prevent the plurality of nano-structures 140 from being damaged due to chemicals (PR, stripper, etc.), an etching liquid, an etching gas, or plasma used in a photo process or an etching process performed in a subsequent operation.

The passivation layer 150 may be formed to have a refractive index lower than the refractive index of the plurality of nano-structures 140. In this case, the passivation layer 150 may be formed of one selected from a group consisting of SiO₂, SiON, SiNₓ, and a combination thereof.

The first and second bonding electrodes 160 and 170 may be formed on and connected to the first and second conductive semiconductor layers 121 and 123. The first bonding electrode 160 and the second bonding electrode 170 may be formed of metallic materials such as Au, Al, and Ag or a transparent conductive material and may have a multi-layered structure of two or more layers.

As shown in FIG. 2, an opening 151 penetrating the transparent electrode layer 130 and the passivation layer 150 may be formed at the second bonding electrode 170, which may be connected to the second conductive semiconductor layer 123.

As such, when the opening 151 is formed and the second bonding electrode 170 comes into contact with the second conductive semiconductor layer 123, electrical resistance may be reduced, thereby improving internal light extraction efficiency.

In the semiconductor light emitting device 100 having the above configuration, the refractive indexes of the transparent electrode layer 130, the plurality of nano-structures 140, and the passivation layer 150 are gradually reduced to form a graded refractive index.

In general, when a difference in refractive indices between interfaces is generated, total internal reflection in which light having a threshold angle or more is reflected internally is generated and the total internal reflection causes external light extraction efficiency to deteriorate. In this case, when the difference in refractive indices between the interfaces is reduced, the threshold angle increases. Therefore, since the light that is internally fully-reflected is reduced, external light extraction efficiency is improved.

Similarly, in the case of the top light emitting-type light emitting device having the horizontal structure, the light emitted from the active layer is dispersed to the air through the second conductive semiconductor layer. In this case, due to a difference in refractive indices between the second conductive semiconductor layer and the air, the light is reflected internally in the second conductive semiconductor layer, and as a result, external light extraction efficiency is reduced.

In the semiconductor light emitting device 100 according to the first embodiment of the present invention, the transparent electrode layer 130 may be formed on the second conductive semiconductor layer 123 and the plurality of nano-structures 140 having a refractive index lower than the transparent electrode layer 130 may be formed therein. Since the plurality of nano-structures 140 are covered by the protection layer 150 having the lower refractive index than the plurality of nano-structures 140, the graded refractive index in which the refractive index is gradually reduced may be formed.

For example, when the transparent electrode layer 130 is formed by an Indium Tin Oxide (ITO) layer, the plurality of nano-structures 140 are formed by a ZnO layer, and the passivation layer 150 is formed by a SiO₂ layer, a refractive index of ITO is 2.0, a refractive index of ZnO is 1.85, and a refractive index of SiO₂ is 1.47, and as a result; the graded refractive index in which the refractive index is gradually reduced is formed.

Therefore, as compared to a case in which light is emitted directly to the air through the second conductive semiconductor layer 123, the difference in refractive indices is reduced, and as a result, external light extraction efficiency is improved by the reduction of total internal reflection.

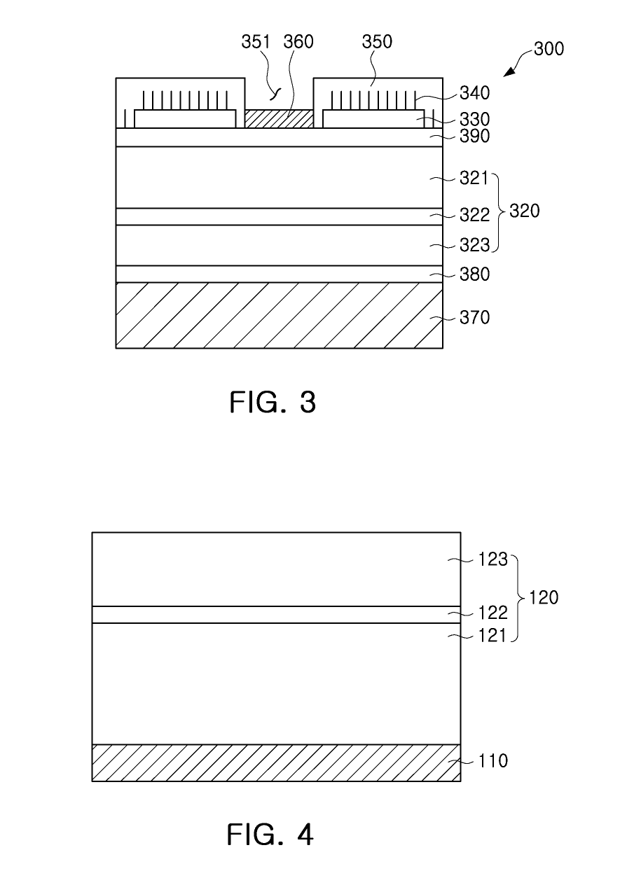

As shown in FIG. 3, a semiconductor light emitting device 300 according to a second embodiment of the present invention is a vertical-structure semiconductor light emitting device. The vertical-structure semiconductor light emitting device 300 is a semiconductor light emitting device in which a light emitting structure 320 is formed on a growth substrate (not shown), a support substrate 370 is attached to the light emitting structure 320, and thereafter, the growth substrate is removed by a laser life-off (LLO) or a chemical lift-off method.

As the support substrate 370 as a substrate attached with the light emitting structure 320, various kinds of substrates may be used, and they are not limited to a particular kind of substrate.

In the semiconductor light emitting device 300 according to the second embodiment of the present invention, a transparent electrode layer 330, a plurality of nano-structures 340, and a passivation layer 350 may be formed on the light emitting structure 320. In this case, refractive indexes of the transparent electrode layer 330, the plurality of nano-structures 240, and the passivation layer 350 may be formed to be sequentially reduced.

Similarly as in the first embodiment described above, the light emitting structure 320 may include a first conductive semiconductor layer 321, a second conductive semiconductor layer 323, with an active layer 322 interposed therebetween. The first conductive semiconductor layer 321 may be the III-V group nitride semiconductor material and for example, the n-GaN layer. The second conductive semiconductor layer 323 may be the III-V group nitride semiconductor layer and for example, the p-GaN layer or p-GaN/AlGaN layer. The active layer 322 may be the GaN-based III-V group nitride semiconductor layer, which is InₓAl_{y}Ga_{1-x-y}N (0≦x≦1, 0≦y≦1, and 0≦x+y≦1) and the multi-quantum well (MQW) in which the quantum barrier layer and the quantum well layer are alternately stacked or the single quantum well. For example, the active layer 322 may be the GaN/InGaN/GaN MQW or GaN/AlGaN/GaN MQW structure.

Similarly to the first embodiment described above, the transparent electrode layer 330 may be formed of any one of the transparent conductive oxide and the transparent conductive nitride. A material forming the transparent electrode layer may be at least one material selected from the group consisting of Indium Tin Oxide (ITO), Zinc-doped Indium Tin Oxide (ZITO), Zinc Indium Oxide (ZIO), Gallium Indium Oxide (GIO), Zinc Tin Oxide (ZTO), Fluorine-doped Tin Oxide (FTC)), Aluminum-doped Zinc Oxide (AZO), Gallium-doped Zinc Oxide (GZO), In₄Sn₃O₁₂, and Zn₍₁₋ₓ₎MgₓO (Zinc Magnesium Oxide, 0≦x≦1).

Similarly as in the first embodiment described above, the plurality of nano-structures 340 may be formed to have a refractive index lower than the refractive index of the transparent electrode layer 330. In this case, the plurality of nano-structures 340 may be formed of the transparent conductive zinc oxide (ZnO)-based compound. The plurality of nano-structures 140 may be formed to have various shapes, that is, the columnar shape, the needle-like shape, the tubular shape, and the platter shape, among polygons having a circular, rectangular or hexagonal horizontal cross-sectional shape. The length of the plurality of nano-structures 340 grown by controlling a reaction time at a growth temperature of the plurality of nano-structures 340 may be controlled. The plurality of nano-structures 340 may be grown on the transparent electrode layer 330 by using the chemical vapor deposition (CVD) method, the molecular beam epitaxy (MBE) method, and the hydride vapor phase epitaxy (HVPE) method, but when the plurality of nano-structures 140 are grown by using the CVD method, the production process may be relatively simple and production costs may be relatively low.

Similarly as in the first embodiment described above, the passivation layer 350 may be formed to cover the plurality of nano-structures 340. The passivation layer 350 protects the plurality of nano-structures and is formed to have a refractive index lower than the refractive index of the plurality of nano-structures 340. In this case, the passivation layer 350 may be formed of one selected from the group consisting of SiO₂, SiON, SiNₓ, and the combination thereof.

Similarly to the first embodiment described above, a first bonding electrode 360 may be formed on the first conductive semiconductor layer 321 to be connected with the first conductive semiconductor layer 321. The first bonding electrode 360 may be formed of the metallic materials such as Au, Al, and Ag or the transparent conductive material and may have the multi-layered structure of two or more layers.

An opening 351 penetrating the transparent electrode layer 330 and the passivation layer 350 may be formed at the first bonding electrode 360, which may be connected to the first conductive semiconductor layer 321.

As such, when the opening 351 is formed and the first bonding electrode 360 comes into contact with the first conductive semiconductor layer 321, the electrical resistance may be reduced, thereby improving internal light extraction efficiency.

A reflection layer 380 may be formed on the bottom of the light emitting structure 320 to reflect light emitted toward the support substrate 370 to be emitted onto a light emitting surface, thereby further improving external light extraction efficiency.

Reference numeral 390 represents a buffer layer for preventing the light emitting structure 320 from being damaged when the growth substrate is separated.

In the vertical-structure semiconductor light emitting device 300 described above, light emitted from the active layer 322 may be emitted toward the transparent electrode layer 330, and the refractive indexes of the plurality of nano-structures 340 and the passivation layer 350 formed on the transparent electrode layer 330 may be sequentially reduced, thereby improving external light extraction efficiency.

Next, referring to FIGS. 4 to 11, a manufacturing method of the semiconductor light emitting device according to the first embodiment of the present invention will be described.

As shown in FIG. 4, first, a light emitting structure 120 including first and second conductive semiconductor layers 121 and 123 with an active layer 122 interposed therebetween may be formed on a prepared substrate 110.

The light emitting structure 120 may be grown by using a metal organic chemical vapor deposition (MOCVD) method, a molecular beam epitaxy (MBE) method, a hydride vapor phase epitaxy (HVPE) method, and the like.

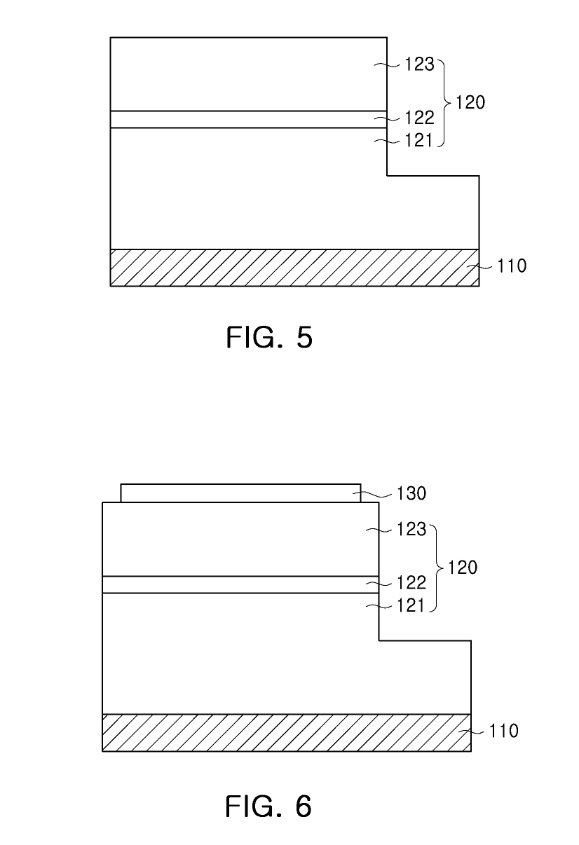

Next, as shown in FIG. 5, partial areas of the first conductive semiconductor layer 121, the second conductive semiconductor layer 123, and the active layer 122 may be mesa-etched.

Next, as shown in FIG. 6, a transparent electrode layer 130 may be formed on the second conductive semiconductor layer 123.

The transparent electrode layer 130 may be formed by a transparent conductive oxide layer and may be formed of at least one selected from a group consisting of Indium Tin Oxide (ITO), Zinc-doped Indium Tin Oxide (ZITO), Zinc Indium Oxide (ZIO), Gallium Indium Oxide (GIO), Zinc Tin Oxide (ZTO), Fluorine-doped Tin Oxide (FTC)), Aluminum-doped Zinc Oxide (AZO), Gallium-doped Zinc Oxide (GZO), In₄Sn₃O₁₂, and Zn₍₁₋ₓ₎MgₓO (Zinc Magnesium Oxide, 0≦x≦1).

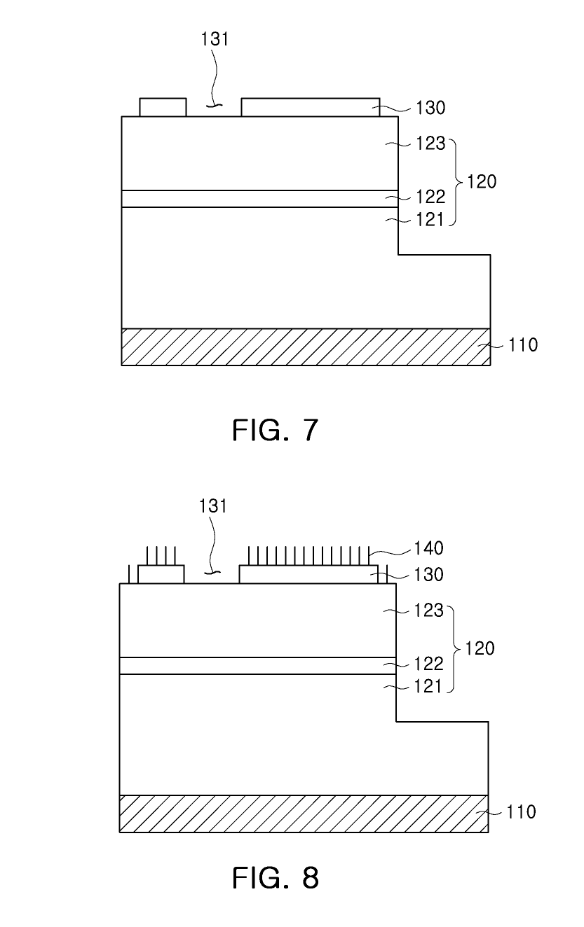

Next, as shown in FIG. 7, the transparent electrode layer 130 may be etched to form an opening 131 in the transparent electrode layer 130.

The opening 131 in the transparent electrode layer 130 may be obtained by etching using various physical and chemical etching methods.

Next, as shown in FIG. 8, a plurality of nano structures 140 may be formed in the transparent electrode layer 130.

The plurality of nano-structures 140 may be grown in the transparent electrode layer 130 by using at least one of the chemical vapor deposition (CVD) method through a chemical reaction, which includes a metalorganic chemical vapor deposition (MOCVD) method, a thermal or e-beam evaporation method, a laser deposition using a laser beam with high-level energy, a sputtering deposition method using a gas ion such as oxygen (O₂), nitrogen (N₂), or argon (Ar), and various physical vapor deposition methods including a co-sputtering deposition method using two or more sputter guns.

The plurality of nano-structures 140 may be heat-treated at a temperature of 800° C. or below under an atmosphere of oxygen (O₂), nitrogen (N₂), hydrogen (H2), argon (Ar), air, and vacuum in order to improve light transmittance and electrical conductivity of the plurality of nano-structures 140.

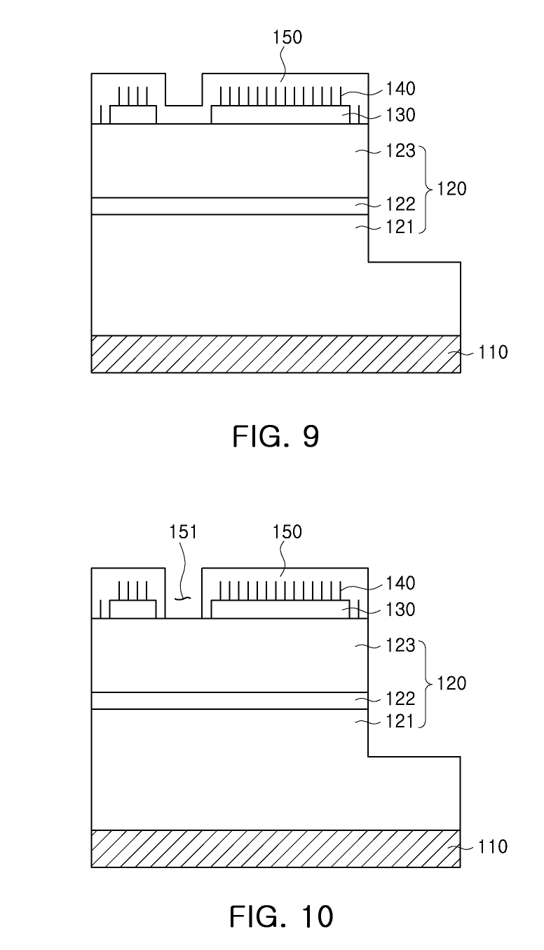

Next, as shown in FIG. 9, a passivation layer 150 may be formed to cover the plurality of nano-structures 140.

The passivation layer 150 may be formed of SiO₂, SiON, or SiNₓ and may be formed of one selected from a group consisting of SiO₂, SiON, SiNₓ, and a combination thereof.

In this case, the passivation layer 150 may be formed by using the CVD method, the sputtering method, or a plasma enhanced chemical vapor deposition (PECVD) method.

The passivation layer 150 may prevent the plurality of nano-structures 140 from being damaged due to chemicals (PR, stripper, and the like), an etching liquid, etching gas, or plasma used in a photo process or an etching process performed in forming an opening 151 or forming first and second bonding electrodes 160 and 170.

Next, as shown in FIG. 10, the opening 151 may be formed by etching the transparent electrode layer 150.

The opening 151 as a space for formation of the second bonding electrode 170 therein on the second conductive semiconductor layer 123 may be formed by using various physical and chemical etching methods similarly to the opening 131 of the transparent electrode layer 130 described above.

For example, SiO₂ at a portion where the opening 151 will be formed may be etched by using at least one of a reactive ion etching (RIE) or inductive coupled plasma/reactive ion etching (ICP/RIE) dry etching method and a buffer oxide etchant (BOE).

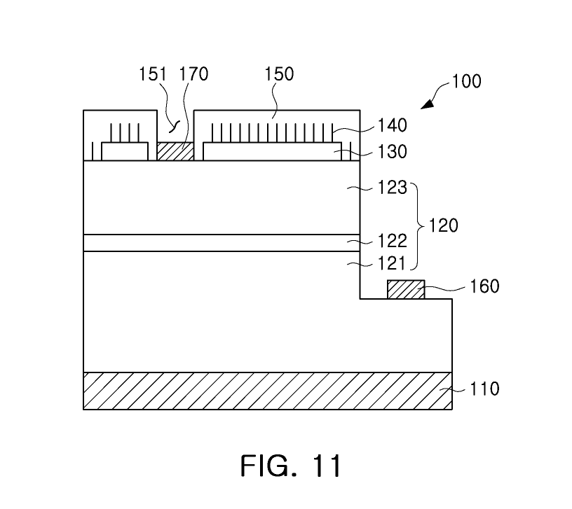

Next, as shown in FIG. 11, the second bonding electrode 170 connected to the second conductive semiconductor layer 123 may be formed in the opening 151, and the first bonding electrode 160 connected to the first conductive semiconductor layer 121 which is mesa-etched may be formed.

Through the above process, the semiconductor light emitting device 100 according to the first embodiment of the present invention may be completed.

As set forth above, according to embodiments of the present invention, in a semiconductor light emitting device, total internal reflection may be reduced to improve light extraction efficiency.

According to embodiments of the present invention, a manufacturing method of the semiconductor light emitting device provides a semiconductor light emitting device in which total internal reflection is reduced to improve light extraction efficiency.

While the present invention has been shown and described in connection with the embodiments, it will be apparent to those skilled in the art that modifications and variations can be made without departing from the spirit and scope of the invention as defined by the appended claims.

What is claimed is:

1. A semiconductor light emitting device, comprising:
a light emitting structure including first and second conductive semiconductor layers with an active layer interposed therebetween;
first and second bonding electrodes connected to the first and second conductive semiconductor layers, respectively;
a transparent electrode layer formed on the second conductive semiconductor layer;
a plurality of nano structures formed on the transparent electrode layer; and
a passivation layer formed to cover the plurality of nano-structures,
wherein refractive indexes of the transparent electrode layer, the plurality of nano-structures, and the passivation layer being sequentially reduced.

2. The semiconductor light emitting device of claim 1, wherein the transparent electrode layer is any one of a transparent conductive oxide layer and a transparent conductive nitride layer.

3. The semiconductor light emitting device of claim 2, wherein the transparent electrode layer is formed of at least one selected from a group consisting of Indium Tin Oxide (ITO), Zinc-doped Indium Tin Oxide (ZITO), Zinc Indium Oxide (ZIO), Gallium Indium Oxide (GIO), Zinc Tin Oxide (ZTO), Fluorine-doped Tin Oxide (FTC)), Aluminum-doped Zinc Oxide (AZO), Gallium-doped Zinc Oxide (GZO), In₄Sn₃O₁₂, and Zn₍₁₋ₓ₎MgₓO (Zinc Magnesium Oxide, 0≦x≦1).

4. The semiconductor light emitting device of claim 3, wherein the plurality of nano-structures are formed of a transparent conductive zinc oxide (ZnO)-based compound.

5. The semiconductor light emitting device of claim 1, wherein the passivation layer is formed of one selected from a group consisting of SiO₂, SiON, SiNₓ, and a combination thereof.

6. The semiconductor light emitting device of claim 1, wherein the transparent electrode layer has an opening, and
the second bonding electrode and the second conductive semiconductor layer are connected therethrough.

7. The semiconductor light emitting device of claim 6, wherein the passivation layer has an opening, and
the second bonding electrode and the second conductive semiconductor layer are connected therethrough.

8. The semiconductor light emitting device of claim 1, wherein the plurality of nano-structures are formed by using the transparent electrode layer as a seed layer.

9. The semiconductor light emitting device of claim 1, wherein the transparent electrode layer is an indium tin oxide (ITO) layer, the plurality of nano-structures are formed of ZnO, and the passivation layer is a SiO₂ layer.

10. A manufacturing method of a semiconductor light emitting device, comprising:
forming a light emitting structure including first and second conductive semiconductor layers with an active layer interposed therebetween;
forming a transparent electrode layer on the second conductive semiconductor layer;
forming a plurality of nano structures on the transparent electrode layer; and
forming a passivation layer to cover the plurality of nano-structures,
wherein refractive indexes of the transparent electrode layer, the plurality of nano-structures, and the passivation layer being sequentially reduced.

11. The manufacturing method of a semiconductor light emitting device of claim 10, further comprising removing the transparent electrode layer and forming a second bonding electrode connected to the second conductive semiconductor layer.

12. The manufacturing method of a semiconductor light emitting device of claim 10, wherein the transparent electrode layer is a transparent conductive oxide layer.

13. The manufacturing method of a semiconductor light emitting device of claim 10, wherein the transparent electrode layer is formed of at least one selected from a group consisting of Indium Tin Oxide (ITO), Zinc-doped Indium Tin Oxide (ZITO), Zinc Indium Oxide (ZIO), Gallium Indium Oxide (GIO), Zinc Tin Oxide (ZTO), Fluorine-doped Tin Oxide (FTC)), Aluminum-doped Zinc Oxide (AZO), Gallium-doped Zinc Oxide (GZO), In₄Sn₃O₁₂, and Zn₍₁₋ₓ₎MgₓO (Zinc Magnesium Oxide, 0≦x≦1).

14. The manufacturing method of a semiconductor light emitting device of claim 10, wherein the passivation layer is formed of one selected from a group consisting of SiO₂, SiON, SiNₓ, and a combination thereof.

15. The manufacturing method of a semiconductor light emitting device of claim 14, wherein the passivation layer is formed by using a chemical vapor deposition (CVD) method.

16. The manufacturing method of a semiconductor light emitting device of claim 14, wherein the passivation layer is formed by using a sputtering method.
